(19) United States
(12) Patent Application Publication
(10) Pub. No.: US 2002/0119760 A1
(43) Pub. Date: Aug. 29, 2002

(54) Method for digital audio broadcasting and receiver therefor

(76) Inventor: Kazuhiro Oyagi, Kanagawa (JP)

Correspondence Address: COOPER & DUNHAM LLP, 1185 Avenue of the Americas, New York, NY, 10036, US

(21) Appl. No.: 10/045,448

(22) Filed: Oct. 25, 2001

(30) Foreign Application Priority Data
Nov. 6, 2000 (JP) P2000-337048

(51) Int. Cl. H04B 1/00; H04B 7/00; H03K 9/00; H04L 27/06; H04L 27/14; H04L 27/22

(52) U.S. Cl. 455/130; 370/310; 375/316

(57) ABSTRACT

A digital audio broadcasting receiver for receiving digital audio broadcasting implemented by multiplexing commercial digital audio data to digital audio data includes a decoder circuit for decoding and outputting the digital audio data and the commercial digital audio data; a memory circuit for storing the commercial digital audio data; a switching circuit for selectively extracting the digital audio data and the commercial audio data stored in the memory circuit; and a detecting circuit for detecting a reception state of the digital audio data. When the digital audio data is not output depending on the reception state of the digital audio data, the commercial digital audio data is automatically output.

### BACKGROUND OF THE INVENTION

1. Field of the Invention

The present invention relates to methods for digital audio broadcasting and receivers therefor.

2. Description of the Related Art

In Europe, digital audio broadcasting in accordance with the Eureka (European Research Coordinating Action) 147 standard, that is, DAB (registered trademark) (Digital Audio Broadcasting) has been implemented. DAB uses:

Transmission bandwidth: 1.5 MHz;

Modulation system: OFDM (Orthogonal Frequency Division Multiplex); and

Data compression system for audio signals: MPEG (Motion Picture Experts Group) Audio Layer II.

Accordingly, DAB multiplexes and broadcasts digital audio data and digital data for a maximum of 64 programs.

In DAB, as shown in FIG. 2A, a program broadcast is performed using a hierarchical structure. As described above, DAB uses a transmission bandwidth of 1.5 MHz for one channel. A transmission channel is referred to as an “ensemble”. A particular ensemble is selectable by tuning in to the center frequency of that ensemble. FIG. 2A shows a case in which the ensemble is named “DIGITAL AUDIO” which is also displayed on a display of a receiver.

The ensemble is divided into transmission channels referred to as “services”. A maximum of 64 channels or services can be used. Each service corresponds to, for example, one FM broadcasting station. In FIG. 2A, the ensemble is divided into four services 1 to 4 which are referred to as “Service 1” to “Service 4”, respectively. These names are also displayed on the display.

When listening to a DAB program, a listener selects an ensemble (frequency) and then selects a desired service (program) from among a plurality of services included in the ensemble.

In general, there are two types of broadcasting: “pay broadcasting” wherein service fees are collected and “free-of-charge broadcasting” wherein there are no service fees. A broadcaster broadcasts commercial messages for companies in order to provide free-of-charge broadcasting or broadcasting wherein the services fees are small. In both free-of-charge broadcasting and in pay broadcasting wherein the service fees are small, it is necessary that receiving apparatuses (hereinafter referred to as receivers) reliably receive commercial messages.

Reception for in-vehicle receivers greatly vary depending on where or how vehicles are travelling. In places such as the inside of a tunnel, a building, and in underground parking lots where reception of radio waves can be impaired or where radio waves are not easily transmitted, the receivers may not be able to receive a broadcast. If commercial messages are aired while the receiver is in one of the above locations, commercial messages will not be heard by listeners.

### SUMMARY OF THE INVENTION

Accordingly, it is an object of the present invention to solve the foregoing problems.

According to an aspect of the present invention, a receiver for digital audio broadcasting which multiplexes and broadcasts program digital audio data and commercial digital audio data is provided. The receiver includes a decoder circuit for decoding and outputting the program digital audio data and the commercial digital audio data; a memory circuit for storing the commercial digital audio data output from the decoder circuit; a switching circuit for selectively obtaining the program digital audio data output from the decoder circuit and the commercial digital audio data stored in the memory circuit; and a detection circuit for detecting a state in which the reception state of the program digital audio data deteriorates and thus becomes unsuitable for playback. When the reception state of the program digital audio data is good, the program digital audio data output from the decoder circuit is obtained from the switching circuit. When the reception state of the program digital audio data deteriorates, the commercial digital audio data stored in the memory circuit is obtained from the switching circuit by controlling the switching circuit using a detection output of the detection circuit.

When the reception state deteriorates and a program which had been being received up until then becomes inaudible, a commercial message will become audible instead.

According to the present invention, when the quality of reception for a receiver to receive a program becomes unsatisfactory, the receiver plays a commercial message which had been stored up until that time in memory, and the commercial message can be reliably broadcast to a listener. Commercial messages are beneficial to companies and listeners as the companies can sponsor programs and the listeners effectively utilize the commercial messages to get information. Also, repetitive playback of commercial messages with the same content enhances advertising effect. Even when the receiver cannot receive a service, the listener can still hear sound.

### BRIEF DESCRIPTION OF THE DRAWINGS

FIG. 1 is a system diagram of a DAB receiver according to an embodiment of the present invention; and

FIGS. 2A and 2B illustrate the present invention.

### DESCRIPTION OF THE PREFERRED EMBODIMENTS

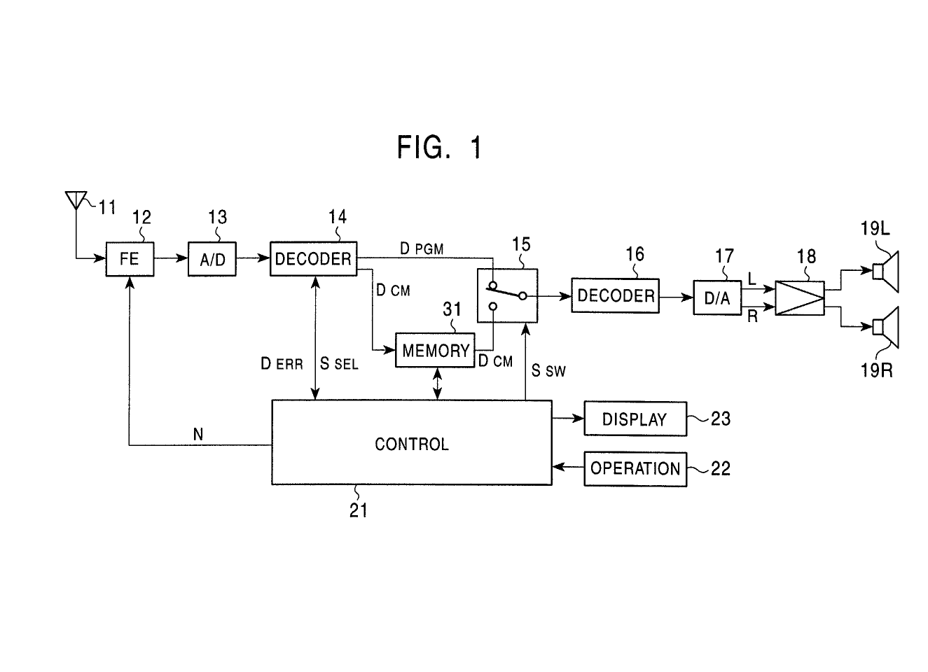

FIG. 1 shows a DAB receiver according to an embodiment of the present invention. The DAB receiver is provided in a vehicle (not shown).

In the DAB receiver, an antenna 11 receives a DAB airwave signal, and the received signal is supplied to a front-end circuit 12. The front-end circuit 12 is formed in accordance with a superheterodyne system. Also, the front-end circuit 12 includes a phase locked loop (PLL) and thus formed in a synthesizer system. By adjusting the division ratio N of a variable frequency divider circuit of the PLL, the reception frequency (ensemble) can be changed.

From the front-end circuit 12, an intermediate frequency (IF) signal of the received DAB is extracted. The signal is supplied to an analog to digital (A/D) converter circuit 13 and is subjected to A/D conversion, thus outputting a digital signal. The digital signal is supplied to a decoder circuit 14 and is subjected to orthogonal demodulation, fast Fourier transform (FFT) demodulation, differential quadrature phase shift keying (D-QPSK) demodulation, frequency de-interleaving, time de-interleaving, and error correction. In accordance with a selection signal SSEL, the decoder circuit 14 selects and outputs digital audio data DPGM for a desired service (program).

The output digital audio data DPGM is supplied through a switching circuit 15 (described below) to an audio decoder circuit 16, thus being subjected to MPEG audio decoding. From the audio decoder circuit 16, decompressed digital audio data DPGM is extracted. The digital audio data DPGM is supplied to a digital to analog (D/A) converter circuit 17 and is subjected to D/A conversion, thus outputting analog audio signals L and R. The signals L and R are supplied through an amplifier 18 to loudspeakers 19L and 19R, respectively.

A system control circuit 21 formed of a microcomputer is provided. The system control circuit 21 supplies data for the division ratio N of the variable frequency divider circuit of the PLL as frequency data for selecting an ensemble (reception frequency) to the front-end circuit 12. Also, the system control circuit 21 supplies a service selection signal SSEL to the decoder circuit 14.

An input operation unit 22 containing various operation keys and dials and an output display unit 23 such as a liquid crystal display (LCD) are connected to the system control circuit 21.

By operating the input operation unit 22, the division ratio N supplied to the front-end circuit 12 is changed, thereby selecting a desired ensemble. A service included in the ensemble is selected by the selection signal SSEL. Accordingly, the decoder circuit 16 outputs digital audio data DPGM for the desired program, thus outputting, from the loudspeakers 19L and 19R, sounds of the desired program. At the same time, the output display unit 23 displays the names of the selected ensemble and service.

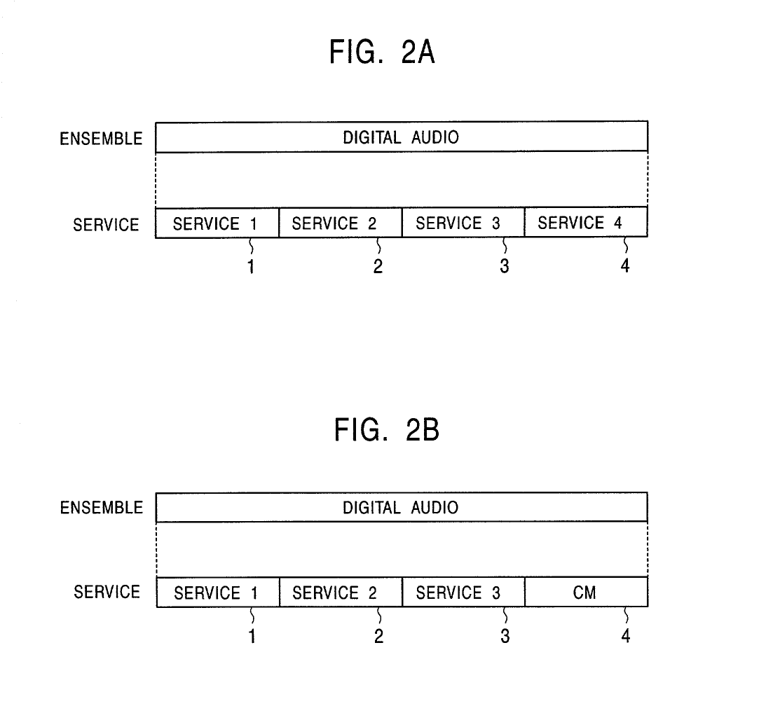

According to the present invention, as shown in FIG. 2B, DAB selects one service from among a plurality of services forming a hierarchical structure and exclusively uses the selected service for commercial use. In an example shown in FIG. 2B, a single ensemble is divided into four channels or services 1 to 4. From among these services 1 to 4, service 4 is exclusively used for commercial use. By using service 4, commercial digital audio data DCM is transmitted. In this case, the commercial digital audio data DCM can be transferred at a relatively low bit rate, depending on the contents of the commercial message and the sponsoring company's intention regarding the commercial message.

From the decoder circuit 14, as described above, the digital audio data DPGM for the desired service and the commercial digital audio data DCM are extracted. The commercial digital audio data DCM is stored in memory circuit 31.

The system control circuit 21 supplies a predetermined read signal to the memory circuit 31 and reads the commercial digital audio data DCM from the memory circuit 31. The read digital audio data DCM is supplied to the switching circuit 15.

From the decoder circuit 14, an error flag DERR is extracted. The error flag DERR indicates whether the error rate of the digital audio data DPGM which is to be output exceeds or falls below a predetermined value. The error flag DERR is supplied to the system control circuit 21. The system control circuit 21 generates a control signal SSW in accordance with the error rate indicated by the error flag DERR and supplies the control signal SSW to the switching circuit 15.

Arranged as described above, when the quality of reception for the receiver to receive a service is satisfactory, the error flag DERR output from the decoder circuit 14 indicates that the error rate of the digital audio data DPGM falls below the predetermined value. Thus, as shown in FIG. 1, the control signal SSW causes the switching circuit 15 to be connected to the decoder circuit 14.

As described above, when the receiver is receiving a service in a satisfactory manner, a listener can listen to an arbitrary service included in the service. At the same time, the commercial digital audio data DCM output from the decoder circuit 14 is sequentially stored in the memory circuit 31.

When the vehicle enters a tunnel, the reception state of the service deteriorates. In such a case, the error flag DEFF indicates that the error rate of the digital audio data DPGM output from the decoder circuit 14 is greater than or equal to the predetermined value.

The error flag DERR is detected by the system control circuit 21. The system control circuit 21 in turn supplies a predetermined read signal to the memory circuit 31 and reads the commercial digital audio data DCM from the memory circuit 31. The control signal SSW changes the connection of the switching circuit 15 such that it is connected to the memory circuit 31 side, which is the side opposite that shown in FIG. 1. Accordingly, the commercial digital audio data DCM is supplied to the audio decoder circuit 16, and a commercial message is automatically output from the loudspeakers 19L and 19R.

When the vehicle has passed through the tunnel and starts receiving a service in a satisfactory manner, the error flag DERR indicates that the error rate of the digital audio data DPGM output from the decoder circuit 14 has fallen below the predetermined value. The system control circuit 21 stops reading the digital audio data DCM from the memory circuit 31, and the switching circuit 15 is connected to the decoder circuit 14, as shown in FIG. 1. Thus, the listener can continue listening to the service he/she had been listening to up until the interruption.

According to the above-described DAB receiver, when the DAB receiver stops receiving a program (service) in a satisfactory manner, the DAB receiver plays a commercial message which had been received and stored up until the interruption in the memory circuit 31. Accordingly, the commercial message can be reliably broadcast to the listener.

In free-of-charge broadcasting or pay broadcasting wherein service fees are small, companies can sponsor programs using commercial messages which are beneficial to the companies and listeners as the listeners can effectively utilize the commercial messages to get information. Even when receivers cannot receive a service, the listeners can still hear sound.

Repetitive playback of commercial messages having the same content can enhance advertising effect. Since only commercial messages are transmitted over the service 4, the commercial messages can be utilized as an advertisement for products or as background music (BGM) by receiving the service 4 and playing the commercial message at a corporate showroom or a shop.

When the above-received DAB receiver stops receiving a service in a satisfactory manner, the DAB receiver plays a commercial message stored in the memory circuit 31. Alternatively, the commercial message stored in the memory circuit 31 can be played while a service of an ensemble which had been received up until then is changed to a service of a different ensemble. In this case, a change or selection of the ensemble can be detected based on input operation by the input operation unit 22 and program data extracted by the decoder circuit 14.

Also, the commercial digital audio data DCM can contain data indicating playback time, and the DAB receiver can include a clock circuit which keeps time and indicates the present time. When the time indicated by the clock circuit matches the playback time included in the commercial digital audio data DCM, a commercial message can be played using the commercial digital audio data DCM.

When the memory circuit 31 is non-volatile, the commercial message can be played by reading the digital audio data DCM from the memory circuit 31 in a period from the time the DAB receiver is turned ON to the time a desired service is reliably received. Alternatively, the commercial message can be played for a predetermined period of time after the DAB receiver is turned ON.

Instead of the commercial digital audio data DCM, digital audio data for information such as news, weather forecast, and traffic information can be transmitted.

What is claimed is:

1. A digital audio broadcasting receiver comprising:
a receiving circuit for receiving multiplexed signals for a plurality of programs;
a separator circuit for separating the plurality of multiplexed program data from the signals received by the receiving circuit;
a program data storage circuit for storing predetermined program data from among the plurality of program data separated by the separator circuit;
a switching circuit for switching between the stored program data to be output from the program data storage circuit and the other program data which is not stored;
a decoder circuit for decoding the program data output by the switching circuit;
a D/A converter circuit for converting the data output from the decoder circuit into analog audio signals;
amplifying/playing means for amplifying and playing the analog audio signals output from the D/A converter circuit; and
a control circuit for controlling the individual circuits and the amplifying/playing means.

2. A digital audio broadcasting receiver according to claim 1, wherein, when the digital audio broadcasting receiver stops receiving signals, the stored program data is selected, and sound is played.

3. A digital audio broadcasting receiver according to claim 1, wherein, at predetermined time, the stored program data is selected, and sound is played.

4. A digital audio broadcasting receiver according to claim 1, wherein, when the digital audio broadcasting receiver is turned ON, the stored program data is selected, and sound is played.

5. A broadcasting method for digital audio broadcasting, comprising the step of multiplexing at least one main program and at least one sub program, wherein the sub program comprises an information service program including a commercial message or news.

6. A broadcasting method for digital audio broadcasting for multiplexing digital audio data for a plurality of channels, comprising the step of broadcasting commercial digital audio data repetitively using at least one channel from among the plurality of channels.

7. A digital audio broadcasting receiver for receiving digital audio broadcasting implemented by multiplexing program digital audio data and commercial digital audio data, comprising:
a decoder circuit for decoding and outputting the program digital audio data and the commercial digital audio data;
a memory circuit for storing the commercial digital audio data output from the decoder circuit;
a switching circuit for selectively extracting the program digital audio data output from the decoder circuit and the commercial digital audio data stored in the memory circuit; and
a detecting circuit for detecting a state in which a reception state of the program digital audio data deteriorates and the program digital audio data becomes unsuitable for playing;
wherein, when the reception state of the program digital audio data is satisfactory, the switching circuit extracts the program digital audio data output from the decoder circuit; and
when the reception state of the program digital audio data deteriorates, the switching circuit is controlled by the detection output of the detecting circuit to extract the commercial digital audio data stored in the memory circuit.
